(19) United States
(12) Patent Application Publication
(10) Pub. No.: US 2026/0130189 A1
(43) Pub. Date: May 7, 2026

(54) DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Ying-Ju WU, Hsinchu (TW); Chia-Yueh CHOU, Taoyuan (TW); Hsiang-Ku SHEN, Hsinchu (TW)

(21) Appl. No.: 18/935,727

(22) Filed: Nov. 4, 2024

(51) Int. Cl. H01L 21/768; H01L 23/522

(52) U.S. Cl. CPC H10W 20/083; H10W 20/075; H10W 20/096; H10W 20/42; H10W 20/496

(57) ABSTRACT

A device structure, along with methods of forming such, are described. The device structure includes an interconnection structure disposed over a substrate, a first dielectric layer disposed over the interconnection structure, and a second dielectric layer disposed on the first dielectric layer. The second dielectric layer comprises a dielectric material having a k value greater than about 20 and a band gap less than about 5 eV. The structure further includes a third dielectric layer disposed on the second dielectric layer and a first conductive feature disposed on the third dielectric layer. The first conductive feature includes a first portion extending through the first dielectric layer, the second dielectric layer, and the third dielectric layer and a second portion disposed on the third dielectric layer.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometric size (i.e., the smallest component that can be created using a fabrication process) has decreased.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, and 1D are cross-sectional side views of various stages of manufacturing a device structure, in accordance with some embodiments.

FIGS. 2A, 2B, 2C, 2D, 2E, 2F, 2G, 2H, and 2I are cross-sectional side views of various stages of manufacturing the device structure, in accordance with alternative embodiments.

FIG. 3 is a cross-sectional side view of one of various stages of manufacturing the device structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated in different embodiments. Additional features can be added to the structure. Some of the features described below can be replaced or eliminated in different embodiments. Although some embodiments are discussed with operations performed in a particular order, these operations may be performed in another logical order.

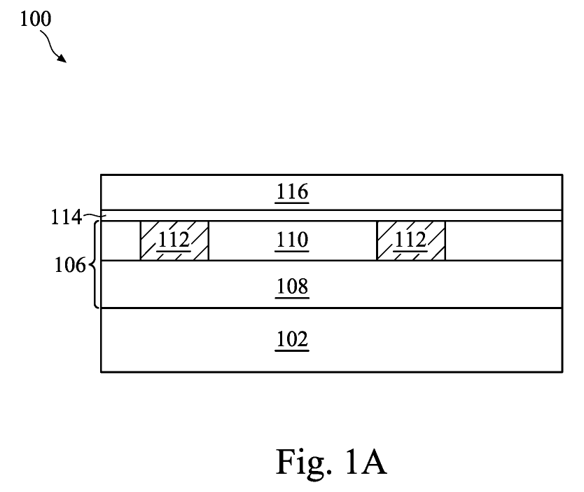

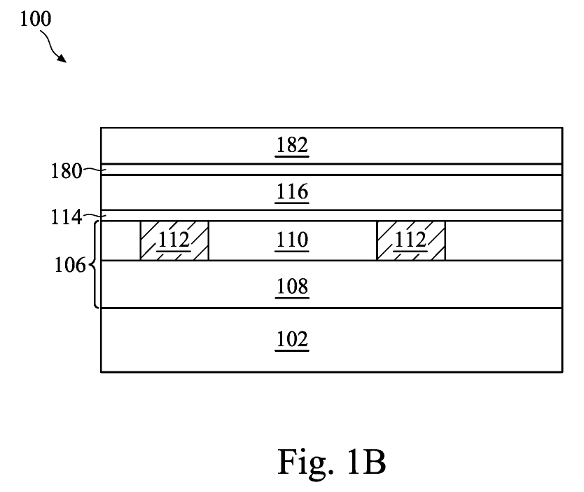

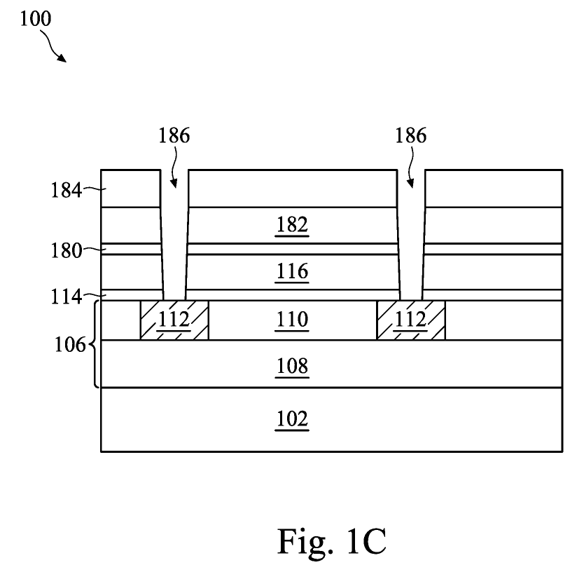

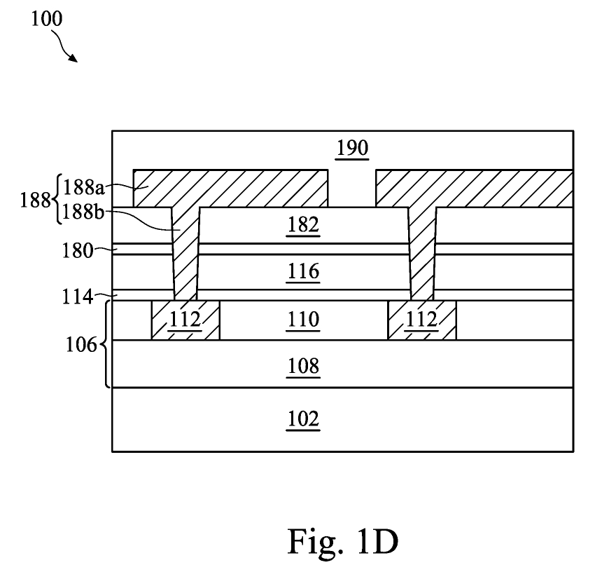

FIGS. 1A-1D are cross-sectional side views of various stages of manufacturing a device structure 100, in accordance with some embodiments. As shown in FIG. 1A, the device structure 100 includes a substrate 102. The substrate 102 may be a semiconductor substrate. In some embodiments, the substrate 102 includes a crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide. In some embodiments, the substrate 102 is a wafer, such as a 200 mm wafer, a 300 mm wafer, a 450 mm wafer, or other suitable sized wafer.

The substrate 102 may include various regions that have been suitably doped with impurities (e.g., p-type or n-type impurities). The dopants are, for example phosphorus for an n-type field effect transistor (NFET) and boron for a p-type field effect transistor (PFET).

In some embodiments, one or more devices are formed on the substrate 102. The one or more devices may be any suitable devices, such as transistors, diodes, imaging sensors, resistors, capacitors, inductors, memory cells, or a combination thereof. In some embodiments, the devices are transistors, such as metal oxide semiconductor field effect transistors (MOSFETs), complementary metal oxide semiconductor (CMOS) transistors, bipolar junction transistors (BJTs), high voltage transistors, high frequency transistors, PFETs/NFETs, or other suitable transistors. The transistors may be planar field effect transistors (FETs), FinFETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels. The one or more devices may be formed by a front end of line (FEOL) process.

As shown in FIG. 1A, the device structure 100 may further include an interconnection structure 106 disposed over the substrate 102. The interconnection structure 106 includes an intermetal dielectric (IMD) layer 108 and a plurality of conductive features (not shown) disposed in the IMD layer 108. The conductive features may be conductive lines and conductive vias. The interconnection structure 106 includes multiple levels of the conductive features, and the conductive features are arranged in each level to provide electrical paths to various devices of the one or more devices therebelow. The conductive features may be made from one or more electrically conductive materials, such as metal, metal alloy, metal nitride, or silicide. For example, the conductive features are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof.

The IMD layer 108 includes one or more dielectric materials to provide isolation functions to various conductive features. The IMD layer 108 may include multiple dielectric layers embedding multiple levels of conductive features. The IMD layer 108 is made from a dielectric material, such as SiOₓ, SiOₓC_{y}H_{z}, or SiOₓC_{y}, where x, y and z are integers or non-integers. In some embodiments, the IMD layer 108 includes a dielectric material having a k value ranging from about 1 to about 5. The IMD layer 108 may be formed by any suitable process, such as chemical vapor deposition (CVD), spin-on, or plasma enhanced chemical vapor deposition (PECVD).

As shown in FIG. 1A, the interconnection structure 106 may further include a dielectric layer 110 and one or more conductive features 112 formed therein. The dielectric layer 110 may be the top layer of the interconnection structure 106. The dielectric layer 110 may include the same material as the IMD layer 108, and the conductive feature 112 may include the same material as the conductive features formed in the IMD layer 108. A barrier layer (not shown) may be disposed between the conductive feature 112 and the dielectric layer 110. The interconnection structure 106 may be formed by a back end of line (BEOL) process.

An etch stop layer 114 may be disposed on the interconnection structure 106, as shown in FIG. 1A. The etch stop layer 114 may include SiC, SiN, SiCN, SiOC, SiOCN, a metal oxide, a metal nitride, or other suitable material. In some embodiments, the etch stop layer has a k value less than about 10 and a band gap greater than about 5.4 eV. In some embodiments, the etch stop layer 114 has a thickness ranging from about 100 nm to about 200 nm. A dielectric layer 116 is disposed on the etch stop layer 114. The dielectric layer 116 may include the same material as the IMD layer 108. In some embodiments, the dielectric layer 116 has a thickness ranging from about 400 nm to about 1000 nm. The dielectric layer 116 may be formed by any suitable process, such as CVD, spin-on, or PECVD.

As shown in FIG. 1A, a dielectric layer 180 is disposed on the dielectric layer 116. The dielectric layer 180 includes a dielectric material having a high k value and low bandgap. In some embodiments, the dielectric material of the dielectric layer 180 has a k value greater than about 20 and a band gap less than about 5 eV. The k value of the dielectric material of the dielectric layer 180 may be between about 20 and about 60, and the band gap of the dielectric material of the dielectric layer 180 may be between about 2.5 eV and about 4.5 eV. In some embodiments, the dielectric layer 180 is made of or includes TiO₂, TiO, BaO, or Ta₂O₅. In some embodiments, the dielectric layer 180 is made of or includes TiO₂, TiO, or BaO. In some embodiments, the dielectric layer 180 is made of or includes TiO₂ or BaO. In some embodiments, the dielectric layer 180 is made of or includes TiO₂. In some embodiments, the dielectric layer 180 is made of or includes BaO. The dielectric layer 180 can provide an electrical current path to discharge static charge accumulated on the device structure 100. During plasma processes, static charge may accumulate on the surfaces of the device structure 100. For example, during subsequent performed plasma etch process to form openings 186 (FIG. 1C) in a dielectric layer 182, the dielectric 180, and the etch stop layer 114, static charge may accumulate on the surfaces of the dielectric layer 182, the dielectric 180, and the etch stop layer 114. With the accumulated static charge, current may flow through the dielectric layers 182, 180, and 114, which may cause device degradation. With the dielectric layer 180 including the dielectric material with a high k value and low band gap, the accumulated static charge may be discharged. The dielectric layer 180 functions as a current path for reducing plasma induced damage (PID). In some embodiments, the dielectric layer 180 has a thickness ranging from about 1 angstrom to about 20 angstroms, such as from about 5 angstroms to about 15 angstroms. If the thickness of the dielectric layer 180 is less than about 5 angstroms, the dielectric layer 180 is not thick enough to provide a current path to discharge the static charge. On the other hand, if the thickness of the dielectric layer 180 is greater than about 15 angstroms, parasitic capacitance may be high due to the high k value of the dielectric layer 180. The dielectric layer 180 may be formed by any suitable process, such as atomic layer deposition (ALD), CVD, or PECVD.

Another dielectric layer 182 is disposed on the dielectric layer 180, as shown in FIG. 1B. In some embodiments, the dielectric layer 182 includes the same material as the dielectric layer 116 and is formed by the same process as the dielectric layer 116. In some embodiments, the dielectric layer 182 has a thickness ranging from about 400 nm to about 1000 nm. In some embodiments, the dielectric layer 182 is formed by PECVD, and the plasma of the PECVD causes the surfaces of the device structure 100 to accumulate static charge. Similarly, in some embodiments, the dielectric layer 116 is formed by PECVD, and the plasma of the PECVD also causes the surfaces of the device structure 100 to accumulate static charge.

As shown in FIG. 1C, a photoresist layer 184 is formed on the dielectric layer 182, and openings 186 are formed in the dielectric layer 182, the dielectric layer 180, the dielectric layer 116, and the etch stop layer 114 to expose the conductive feature 112. The openings 186 may be formed by one or more etch processes. The etch processes may be dry etch processes, wet etch processes, or combinations thereof. In some embodiments, the one or more etch processes are plasma etch processes. As a result, static charge may be accumulated on the surfaces of the device structure 100. The static charge accumulated on the surfaces of the device structure 100 as a result of the plasma etch process to form the openings 186 and/or the PECVD processes to form the dielectric layers 116, 182 is discharged by the dielectric layer 180. The dielectric layer 180 is electrically connected to the subsequently formed conductive features 188 (FIG. 1D), and the static charge may be discharged via the conductive features 188.

In some embodiments, the dielectric layer 180 is not an etch stop layer, because there is no need for an etch stop layer between the dielectric layer 116 and the dielectric layer 182 during the formation of the openings 186. In some embodiments, due to the presence of the dielectric layer 180, which includes a material different from the material of the dielectric layers 116, 182, three distinct etch processes may be performed. For example, a first etch process is performed to remove portions of the dielectric layer 182, a second etch process is performed to remove portions of the dielectric layer 180 exposed by the removal of the portions of the dielectric layer 182, and a third etch process is performed to remove portions of the dielectric layer 116 exposed by the removal of the portions of the dielectric layer 180. Without the dielectric layer 180, the openings 186 may be formed by a single etch process, because the dielectric layer 116 and the dielectric layer 182 include the same material. However, without the dielectric layer 180, the static charge accumulated on the surfaces of the dielectric layers 116, 182 may lead to device degradation.

As shown in FIG. 1D, the conductive feature 188 is formed in each opening 186. The conductive feature 188 may include an electrically conductive material, such as a metal. In some embodiments, the conductive feature 188 includes the same material as the conductive feature 112. In some embodiments, the conductive feature 188 includes copper. The conductive feature 188 includes a via portion 188a and a line portion 188b, as shown in FIG. 1D. The via portion 188a extends through the etch stop layer 114, the dielectric layer 116, the dielectric layer 180, and the dielectric layer 182. The line portion 188b is formed on the dielectric layer 182. The conductive feature 188 may be formed by any suitable process. In some embodiments, the conductive feature 188 is a redistribution layer (RDL).

After the formation of the conductive features 188, a dielectric material 190 is formed on the dielectric layer 182 and the conductive features 188. The dielectric material 190 may be any suitable dielectric material. In some embodiments, the dielectric material 190 is a polymer, such as polyimide. The dielectric material 190 may be formed by any suitable process, such as spin coating, CVD, FCVD, or laminating.

As described above, the static charge accumulated on the surfaces of the dielectric layers 182, 116 may be discharged via the dielectric layer 180 and the conductive feature 188.

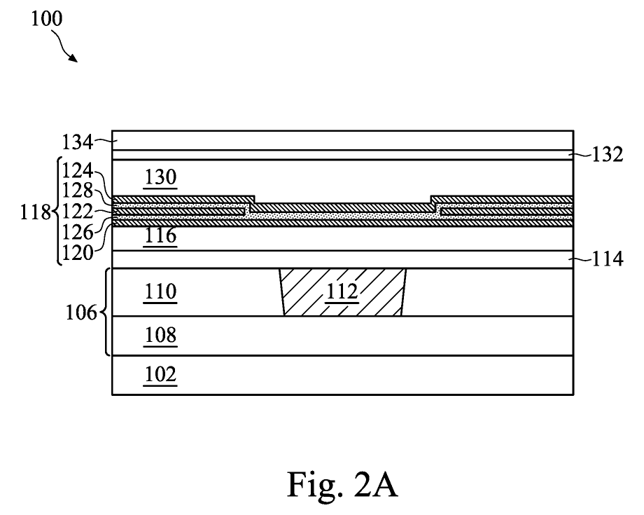

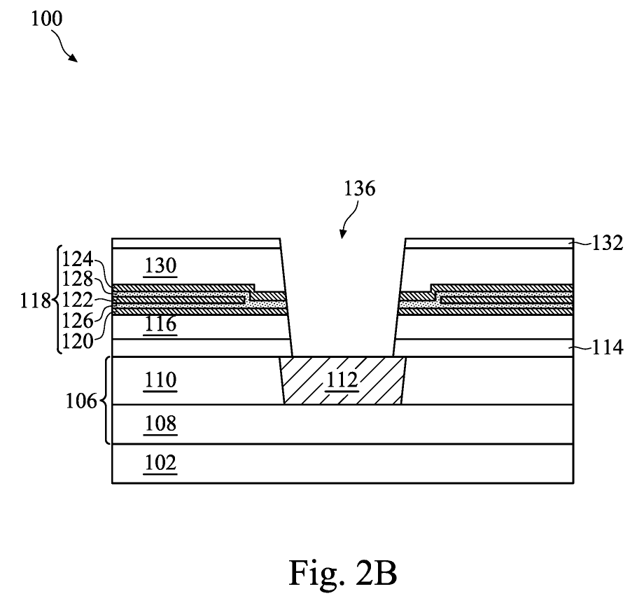

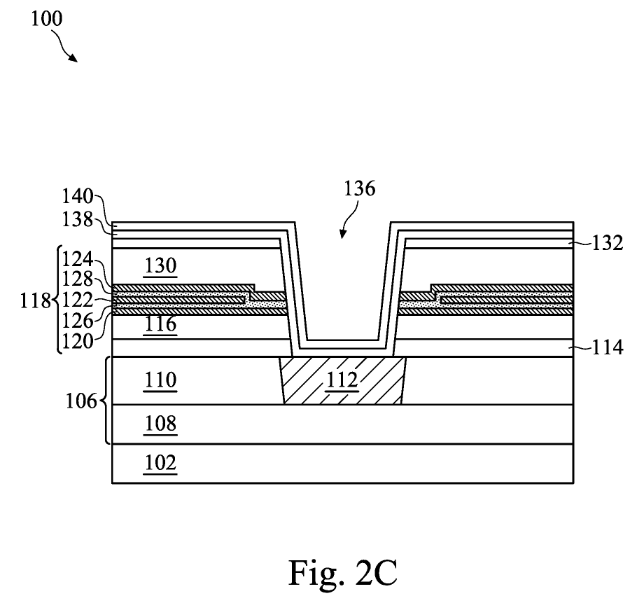

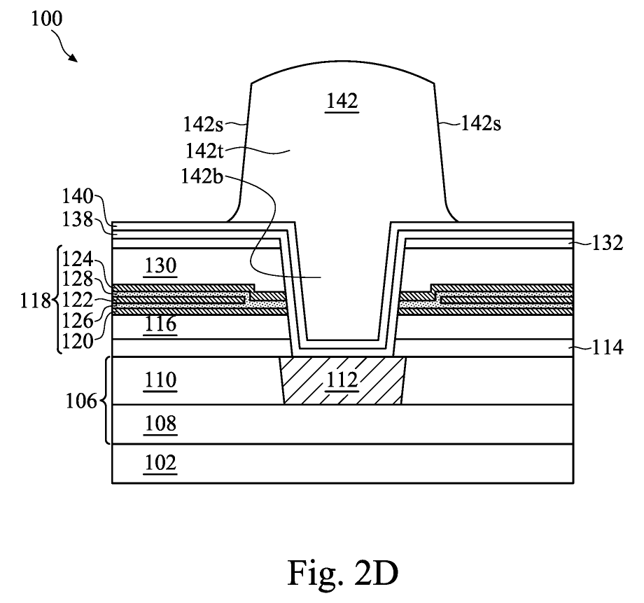

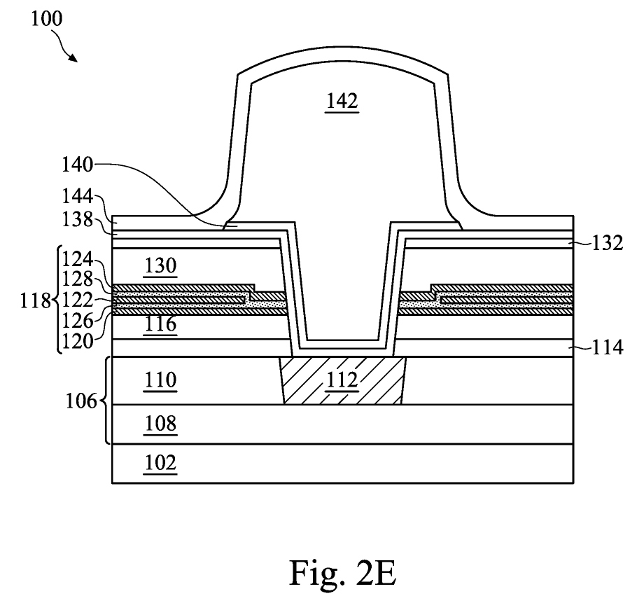

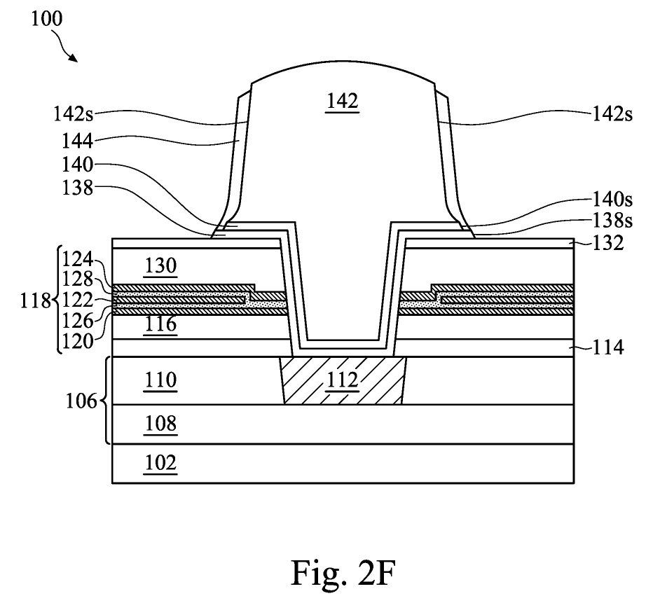

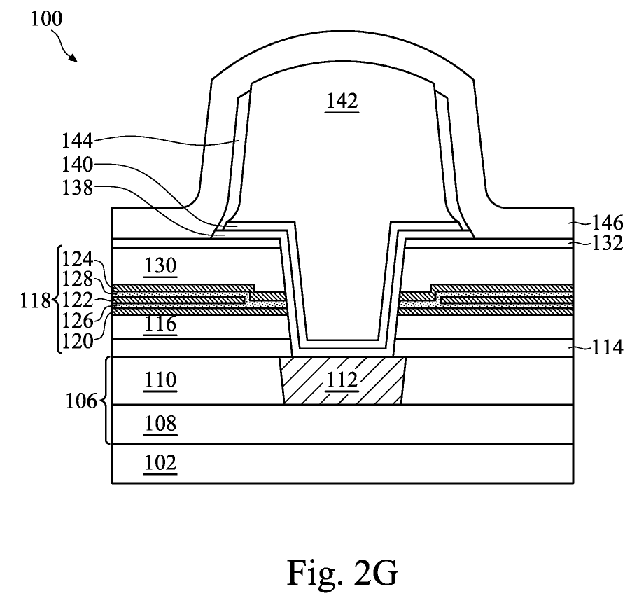

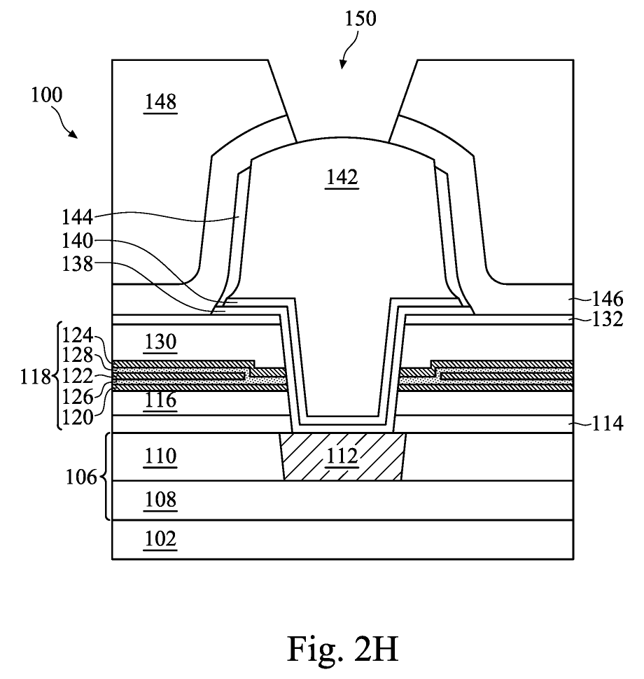

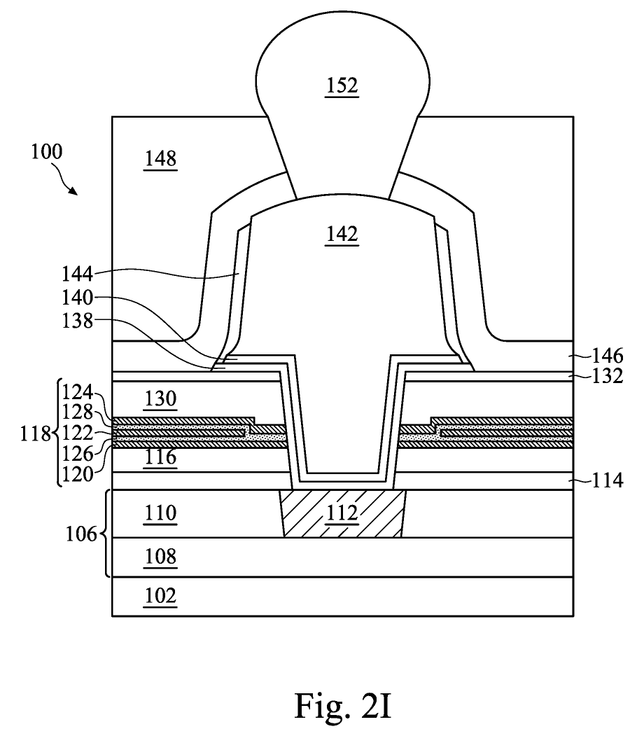

FIGS. 2A - 2I are cross-sectional side views of various stages of manufacturing the device structure 100, in accordance with alternative embodiments. As shown in FIG. 2A, the semiconductor device structure 100 includes the substrate 102 and the interconnection structure 106 is disposed over the substrate 102. One or more devices, such as the one or more devices described in FIG. 1A, may be disposed on the substrate 102. The interconnection structure 106 includes the IMD layer 108, the dielectric layer 110, and the conductive feature 112 formed in the dielectric layer 110, as shown in FIG. 2A. The etch stop layer 114 and the dielectric layer 116 may be disposed on the interconnection structure 106.

As shown in FIG. 2A, a metal-insulator-metal (MIM) structure 118 is disposed on the dielectric layer 116, and a passivation layer 130 is disposed on the MIM structure 118. The MIM structure 118 includes a first electrode layer 120, a second electrode layer 122 disposed over the first electrode layer 120, and a third electrode layer 124 disposed over the second electrode layer 122. The first, second, and third electrode layers 120, 122, 124 may include an electrically conductive material, such as a metal or a metal nitride. In some embodiments, the first, second, and third electrode layers 120, 122, 124 may include Al, Cu, W, Ti, Ta, TiN, TaN, or other suitable electrically conductive material.

The MIM structure 118 further includes a dielectric layer 126 disposed between the first and second electrode layers 120, 122, and a dielectric layer 128 is disposed between the second and third electrode layers 122, 124. In some embodiments, the dielectric layers 126, 128 may include the same material as the dielectric layer 180. Compared to the conventional dielectric material of a MIM structure, the dielectric layers 126, 128 include the dielectric material having a low band gap, which can function as a current path to discharge static charge accumulated on the surfaces of the semiconductor device structure 100 as a result of plasma processes. In some embodiments, the dielectric material of the dielectric layers 126, 128 has a k value greater than about 20 and a band gap less than about 5 eV. The k value of the dielectric material of the dielectric layers 126, 128 may be between about 20 and about 60, and the band gap of the dielectric material of the dielectric layers 126, 128 may be between about 2.5 eV and about 4.5 eV. In some embodiments, the dielectric layers 126, 128 are made of or include TiO₂, TiO, BaO, or Ta₂O₅.

In some embodiments, one of the dielectric layers 126, 128 includes the same material as the dielectric layer 180, and the other of the dielectric layers 126, 128 includes a high k dielectric material having a k value greater than about 7. In some embodiments, one of the dielectric layers 126, 128 includes the high k dielectric material, which may be an oxide of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, or other suitable material. In some embodiments, the k value of the dielectric layer of the dielectric layers 126, 128 that includes the same material as the dielectric layer 180 is greater than the k value of the dielectric layer of the dielectric layers 126, 128 that includes the high k dielectric material. For example, one of the dielectric layers 126, 128 includes BaO, which has a k value of about 33 and a band gap of about 4.3 eV, and the other of the dielectric layers 126, 128 includes HfO₂, which has a k value of about 24 and a band gap of about 6 eV. The low band gap of the dielectric layer that includes BaO can discharge accumulated static charge, but the high k value of the dielectric layer that includes BaO may lead to increased parasitic capacitance. Thus, if both dielectric layers 126, 128 include BaO, the parasitic capacitance of the MIM structure 118 may be too high.

In some embodiments, the thicknesses of the dielectric layers 126, 128 are different. For example, the dielectric layer of the dielectric layers 126, 128 that includes a low band gap dielectric material may be thinner than the dielectric layer of the dielectric layers 126, 128 that includes a high k dielectric material. Because the k value of the low band gap dielectric material may be greater than the k value of the high k dielectric material, parasitic capacitance may be too high if the thickness of the dielectric layer of the dielectric layers 126, 128 that includes the low band gap dielectric material is the same as the thickness of the dielectric layer of the dielectric layers 126, 128 that includes the high k dielectric material. In some embodiments, the thickness of the dielectric layer of the dielectric layers 126, 128 that includes the low band gap dielectric material ranges from about 1 angstrom to about 20 angstroms, such as from about 5 angstroms to about 15 angstroms, and the thickness of the dielectric layer of the dielectric layers 126, 128 that includes the high k dielectric material is greater than about 20 angstroms, such as from about 25 angstroms to about 100 angstroms.

In some embodiments, one of the dielectric layers 126, 128 includes two or more dielectric layers. For example, the dielectric layer 126 (or the dielectric layer 128) includes a first dielectric layer made of a low band gap dielectric material and a second dielectric layer made of a high k dielectric material. The first dielectric layer may include TiO₂, TiO, BaO, or Ta₂O₅, and the second dielectric layer may include an oxide of Li, Be, Mg, Ca, Sr, Sc, Y, Zr, Hf, Al, La, Ce, Pr, Nd, Sm, Eu, Gd, Tb, Dy, Ho, Er, Tm, Yb, Lu. The k value of the second dielectric layer is less than the k value of the first dielectric layer, and the band gap of the second dielectric layer is greater than the band gap of the first dielectric layer. The other dielectric layer 128 (or the dielectric layer 126) may include a single dielectric layer, such as a dielectric layer made of the high k dielectric material.

In some embodiments, the dielectric layer 126 (or the dielectric layer 128) includes a first dielectric layer made of a low band gap dielectric material, a second dielectric layer made of a high k dielectric material, and a third dielectric layer made of the low band gap dielectric material. The second dielectric layer is disposed between the first and third dielectric layers. In some embodiments, the first and third dielectric materials are made of the same low band gap dielectric material. Thus, the k value of the first and third dielectric layers is greater than the k value of the second dielectric layer, and the band gap of the first and third dielectric layers is less than the band gap of the second dielectric layer. The first and third dielectric layers may each include TiO₂, TiO, BaO, or Ta₂O₅, and the second dielectric layer may include an oxide of Li, Be, Mg, Ca, Sr, Sc, Y, Zr, Hf, Al, La, Ce, Pr, Nd, Sm, Eu, Gd, Tb, Dy, Ho, Er, Tm, Yb, Lu. The other dielectric layer 128 (or the dielectric layer 126) may include a single dielectric layer, such as a dielectric layer made of the high k dielectric material.

As shown in FIG. 2A, a passivation layer 130 is disposed over the MIM structure 118. The passivation layer 130 may include an oxide or SiN. In some embodiments, the passivation layer 130 includes the same material as the dielectric layer 116. In some embodiments, the thickness of the passivation layer 130 may be greater than or equal to the thickness of the dielectric layer 116. For example, the thickness of the passivation layer 130 may range from about 350 nm to about 550 nm.

A buffer layer 132 is disposed on the passivation layer 130, and a mask layer 134 is disposed on the buffer layer 132, as shown in FIG. 2A. The buffer layer 132 may include a metal oxide, such as aluminum oxide (AlₓO_{y}), where x and y may be integers or non-integers. The material of the buffer layer 132 may be different from a material of a subsequently formed barrier layer 138 (FIG. 2C) in order to have different etch selectivity compared to the barrier layer 138. The buffer layer 132 may be formed by any suitable process, such as ALD, CVD, or PVD. In some embodiments, the buffer layer 132 is a conformal layer formed by a conformal process, such as ALD. The term “conformal” may be used herein for ease of description upon a layer having substantial same thickness over various regions. The thickness of the buffer layer 132 may be at least 1 nm in order to function as a stress release buffer layer. In some embodiments, the thickness of the buffer layer 132 ranges from about 1 nm to about 50 nm. If the thickness of the buffer layer 132 is less than about 1 nm, the buffer layer 132 may not be sufficient to release stress. On the other hand, if the thickness of the buffer layer 132 is greater than about 50 nm, manufacturing cost may be increased without significant advantages. In addition, the buffer layer 132 may function as an etch stop layer during the removal of a portion of the barrier layer 138. Thus, in some embodiments, the thickness of the buffer layer 132 depends on the thickness of the barrier layer 138, which is described in detail in FIG. 2C.

The mask layer 134 may include one or more layers. In some embodiments, the mask layer 134 includes a nitride, such as TiN. The mask layer 134 may be patterned by a patterned resist layer (not shown) formed on the mask layer 134. The pattern of the patterned resist layer may be transferred to the mask layer 134, which is then transferred to the layers disposed under the mask layer 134.

As shown in FIG. 2B, an opening 136 is formed in the buffer layer 132, the passivation layer 130, the MIM structure 118, and the etch stop layer 114 to expose the conductive feature 112. The opening 136 may be formed by one or more etch processes. The etch processes may be dry etch processes, wet etch processes, or combinations thereof. In some embodiments, the portion of the mask layer 134 (FIG. 1A) is removed by a dry etch process, the portion of the buffer layer 132 is removed by a wet etch process, and the portions of the passivation layer 130, the MIM structure 118, the dielectric layer 116, and the etch stop layer 114 are removed by one or more dry etch processes. In some embodiments, the dry etch processes are plasma etch process, and static charge may accumulate on the surfaces of the device structure 100, such as on the surfaces of the dielectric layer 116, the etch stop layer 114, and the passivation layer 130. The accumulated static charge may be discharged by one or both of the dielectric layers 126, 128. The mask layer 134 may be removed as a result of the multiple etch processes.

As shown in FIG. 2C, a barrier layer 138 is formed on the buffer layer 132 and in the opening 136, and a seed layer 140 is formed on the barrier layer 138. The barrier layer 138 may prevent diffusion of metal from a subsequently formed conductive feature 142 (FIG. 1D) into the passivation layer 130 and the dielectric layers 116, 126, 128. As shown in FIG. 2C, the barrier layer 138 is in contact with the passivation layer 130, the MIM structure 118, the dielectric layer 116, the etch stop layer 114, and the conductive feature 112. The barrier layer 138 may include a nitride, such as a metal nitride, for example a refractory metal nitride. In some embodiments, the barrier layer 138 includes an electrically conductive material. In some embodiments, the barrier layer 138 includes tantalum nitride (TaN). The barrier layer 138 may be formed by any suitable process, such as ALD, CVD, or PVD. In some embodiments, the barrier layer 138 is a conformal layer formed by a conformal process. The barrier layer 138 may have a thickness ranging from about 1 nm to about 50 nm. If the thickness of the barrier layer 138 is less than about 1 nm, the barrier layer 138 may not be sufficient to prevent diffusion of metal. On the other hand, if the thickness of the barrier layer 138 is greater than about 50 nm, manufacturing cost may be increased without significant advantages.

The seed layer 140 may include the same material as the conductive feature 112 and may be formed by any suitable process, such as ALD, CVD, or PVD. In some embodiments, the seed layer 140 is a conformal layer formed by ALD.

As shown in FIG. 2D, the conductive feature 142 is formed in the opening 136 (FIG. 2C) and over portions of the passivation layer 130 and portions of the barrier layer 138. The conductive feature 142 may be formed by first forming a sacrificial layer (not shown) in the opening 136 and over the passivation layer 130. The sacrificial layer may be formed on the seed layer 140. In some embodiments, the sacrificial layer is a resist layer. The sacrificial layer may be patterned so the portions of the sacrificial layer disposed in the opening 136 and over portions of the passivation layer 130 are removed. In other words, an opening is formed by removing the portions of the sacrificial layer. The opening may include the opening 136 (FIG. 2C) and a larger opening in the sacrificial layer over the opening 136 and over portions of the passivation layer 130. Then, the conductive feature 142 is formed in the opening, and the sacrificial layer is removed by a stripping process. The conductive feature 142 formed by this process does not experience a dry etch process, which may affect the roughness of the side surfaces 142s of the conductive feature 142. Subsequently formed adhesion layer 144 (FIG. 2E) on the side surfaces 142s may have poor adhesion to the side surfaces 142s if the side surfaces 142s have exposed to a dry etch process. Thus, without using a dry etch process to form the conductive feature 142, the adhesion layer 144 (FIG. 2E) may have improved adhesion to the side surfaces 142s of the conductive feature 142. In some embodiments, the conductive feature 142 is an RDL. In some embodiments, the conductive feature 188 (FIG. 1D) is formed by the same process as the conductive feature 142.

The conductive feature 142 may include an electrically conductive material, such as a metal. The conductive feature 142 may include the same material as the seed layer 140. In some embodiments, the seed layer 140 and the conductive feature 142 include Cu. In some embodiments, the seed layer 140 is optional, and the conductive feature 142 is formed on the barrier layer 138. The conductive feature 142 may extend through the passivation layer 130, the MIM structure 118, and the dielectric layer 116. The conductive feature 142 may be electrically connected to the conductive feature 112 and the first and third electrode layers 120, 124 of the MIM structure 118. The conductive feature 142 may be formed by any suitable process, such as PVD or ECP. The conductive feature 142 includes a bottom portion 142b disposed in the opening 136 (FIG. 2C) and a top portion 142t located over the bottom portion. In some embodiments, the bottom portion 142b may be a conductive via, and the top portion 142t may be a conductive line. The top portion 142t of the conductive feature 142 may be disposed on portions of the seed layer 140, and the rest of the seed layer 140 may be exposed.

As shown in FIG. 2E, the exposed portions of the seed layer 140 are removed, and the adhesion layer 144 is formed on the top portion 142t of the conductive feature 142. The removal of the exposed portions of the seed layer may be performed by a wet etch process. The wet etch process may remove insignificant amount of the top portion 142t of the conductive feature 142. However, because it is not a dry etch process, adhesion of the adhesion layer 144 to the top portion 142t of the conductive feature 142 is not substantially affected. The adhesion layer 144 may be formed on portions of the barrier layer 138 and on the top portion 142t of the conductive feature 142. The adhesion layer 144 may be a nitride, such as SiN. In some embodiments, the conductive feature 142 has a tensile stress, and the adhesion layer 144 also has a tensile stress in order to better adhere to the top portion 142t of the conductive feature 142. The adhesion layer 144 may be formed by any suitable process, such as ALD, CVD, PECVD, or PVD. The adhesion layer 144 may have a thickness ranging from about 10 nm to about 50 nm.

As shown in FIG. 2F, portions of the adhesion layer 144 and portions of the barrier layer 138 are removed. The portions of the adhesion layer 144 may be removed by an anisotropic etch process. The anisotropic etch process may be a dry etch process that removes portions of the adhesion layer 144 formed on horizontal surfaces, such as the portions of the adhesion layer 144 formed on the top surface of top portion 142t of the conductive feature 142 and on the barrier layer 138. As a result, the portions of the barrier layer 138 located under the removed portions of the adhesion layer 144 are exposed, and the side surfaces 142s are covered by the adhesion layer 144.

Next, because the barrier layer 138 may include an electrically conductive material, the exposed portions of the barrier layer 138 may be removed. In order to protect the side surfaces 142s of the top portion 142t of the conductive feature 142, the adhesion layer 144 is formed on the side surfaces 142s of the top portion 142t of the conductive feature 142 prior to the removal of the exposed portions of the barrier layer 138. Thus, instead of removing the exposed portions of the barrier layer 138 immediately after the removal of the exposed portions of the seed layer 140, additional processes may be performed, such as forming the adhesion layer 144 and removing portions of the adhesion layer 144 to expose portions of the barrier layer 138, in order to protect the side surfaces 142s of the top portion 142t of the conductive feature 142.

As shown in FIG. 2F, after the removal of the exposed portions of the barrier layer 138, side surfaces 138s of the barrier layer 138 are exposed. The seed layer 140 includes side surfaces 140s, and the adhesion layer 144 is in contact with the barrier layer 138, the side surfaces 140s of the seed layer 140, and the side surfaces 142s of the top portion 142t of the conductive feature 142. The side surfaces 138s of the barrier layer 138 may extend outward from the side surfaces 140s of the seed layer 140, and the difference between the side surface 138s and the side surface 140s may be the thickness of the adhesion layer 144, which may range from about 10 nm to about 50 nm.

As shown in FIG. 2G, a passivation layer 146 is formed on the buffer layer 132, the side surfaces 138s of the barrier layer 138, the adhesion layer 144, and the top surface of the top portion 142t of the conductive feature 142. The passivation layer 146 may include the same material as the adhesion layer 144, so the passivation layer 146 is adhered to the adhesion layer 144. In some embodiments, the passivation layer 146 has compressive stress in order to protect the conductive feature 142 from the compressive stress of the subsequently formed conductive feature 152 (FIG. 2I). The passivation layer 146 with compressive stress may not adhere to the side surfaces 142s of the top portion 142t of the conductive feature 142. Thus, as described above, the adhesion layer 144 with tensile stress is utilized so the passivation layer 146 can adhere to the adhesion layer 144, and the adhesion layer 144 can adhere to the side surfaces 142s of the top portion 142t of the conductive feature 142.

In some embodiments, the adhesion layer 144 and the passivation layer 146 include the same material but have different stress. The stress of the adhesion layer 144 and the passivation layer 146 can be controlled by various factors, such as plasma power and/or precursor flow. For example, in some embodiments, the adhesion layer 144 includes SiN having tensile stress and is formed by a first PECVD process. The passivation layer 146 includes SiN having compressive stress and is formed by a second PECVD process. The first PECVD process has a first plasma power and a first silicon-containing precursor flow rate. The second PECVD process has a second plasma power substantially greater than the first plasma power and a second silicon-containing precursor flow rate substantially greater than the first silicon-containing precursor flow rate. The silicon-containing precursor in both the first and second PECVD processes may be silane.

In some embodiments, the passivation layer 146 has a thickness ranging from about 500 nm to about 1500 nm, such as from about 800 nm to about 1200 nm. As described above, the adhesion layer 144 has a thickness ranging from about 10 nm to about 50 nm. In some embodiments, the thickness of the passivation layer 146 may be about 10 to 150 times the thickness of the adhesion layer 144. If the thickness of the passivation layer 146 is less than about 10 times the thickness of the adhesion layer 144, the passivation layer 146 may not sufficiently protect the conductive feature 142 from the stress of the conductive feature 152 (FIG. 2I). On the other hand, if the thickness of the passivation layer 146 is more than about 150 times the thickness of the adhesion layer 144, the risk of the passivation layer 146 being peeled away from the conductive feature 142 is increased.

As shown in FIG. 2H, a dielectric material 148 is formed on the passivation layer 146, and an opening 150 is formed in the dielectric material 148 and the passivation layer 146 to expose the conductive feature 142. The dielectric material 148 may be any suitable dielectric material. In some embodiments, the dielectric material 148 is a polymer, such as polyimide. The dielectric material 148 may be formed by any suitable process, such as spin coating, CVD, FCVD, or laminating. The opening 150 may be formed by any suitable process, such as dry etch, wet etch, or a combination thereof.

As shown in FIG. 2I, the conductive feature 152 is formed in the opening 150 (FIG. 2H). In some embodiments, the conductive feature 152 may be in contact with the conductive feature 142. The conductive feature 152 may include an electrically conductive material, such as a metal. In some embodiments, the conductive feature 152 includes Cu, Ni, Au, Ag, Pd, Al, Sn, or other suitable metal. In some embodiments, the conductive feature 152 is a conductive bump, as shown in FIG. 2I. As shown in FIG. 2I, in some embodiments, the passivation layer 146 is in contact with the buffer layer 132, the barrier layer 138, the adhesion layer 144, the conductive feature 142, the dielectric material 148, and the conductive feature 152.

The processes described in FIGS. 2E to 2I may be also performed on the device structure 100 shown in FIG. 1D. In some embodiments, the dielectric material 190 shown in FIG. 1D is the dielectric material 148 shown in FIG. 2I, and the device structure 100 shown in FIG. 1D also includes the buffer layer 132, the barrier layer 138, the seed layer 140, the adhesion layer 144, the passivation layer 146, and the conductive feature 152.

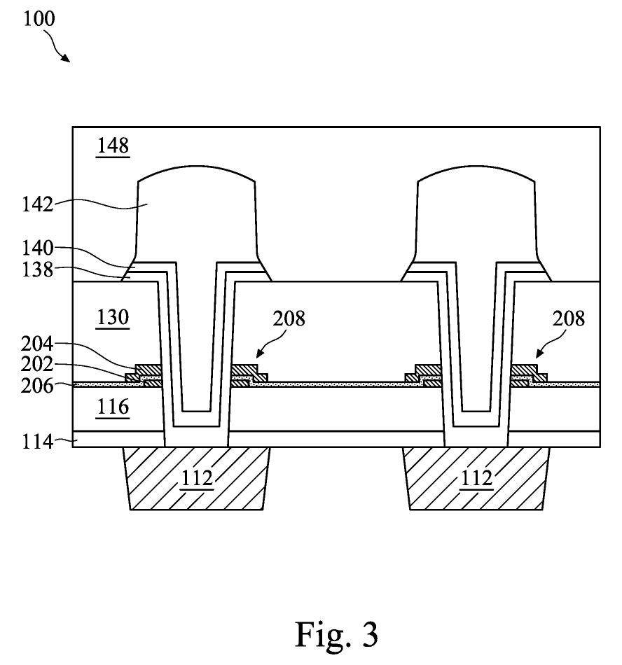

FIG. 3 is a cross-sectional side view of one of various stages of manufacturing the device structure 100, in accordance with alternative embodiments. In some embodiments, the device structure 100 includes the dielectric layer 116 disposed on the etch stop layer 114, which is disposed on the conductive features 112. The dielectric layer 110 is omitted in FIG. 3 for clarity. A first electrode layer 120 is disposed on the dielectric layer 116, a dielectric layer 206 is disposed on the dielectric layer 1126 and the first electrode layer 120, and a second electrode layer 204 is disposed on the dielectric layer 206. The first and second electrode layers 202, 204 may include the same material as the first electrode layer 120. The first electrode layer 202 and the second electrode layer 204 may be patterned to form multiple MIM structures 208 (two are shown), and the dielectric layer 206 is disposed between the first electrode layer 202 and the second electrode layer 204 in all of the MIM structures 208. For example, a continuous conductive layer is first deposited on the dielectric layer 116, and the continuous conductive layer is then patterned to form multiple first electrode layers 202 on the dielectric layer 116. Next, the dielectric layer 206 is deposited on the dielectric layer 116 and the first electrode layers 202. The dielectric layer 206 may be a continuous layer disposed on the multiple first electrode layers 202. Another continuous conductive layer is deposited on the dielectric layer 206, and the continuous conductive layer is patterned to form multiple second electrode layers 204 over corresponding first electrode layers 202. In some embodiments, the dielectric layer 206 includes the same material as the dielectric layer 180, and the dielectric layer 206 functions as a current path for reducing plasma induced damage (PID). Thus, in some embodiments, the dielectric layer 206 extends across the entire substrate 102 (FIG. 1A) to discharge accumulated static charge in various layers of the device structure 100. In some embodiments, the dielectric layer 206 includes two or more layers, such as the two or more dielectric layers of one of the dielectric layers 126, 128 described in FIG. 2A.

As shown in FIG. 3, the passivation layer 130 is formed on the dielectric layer 206 and the second electrode layers 204. The conductive features 142 extends through the passivation layer 130, the multiple MIM structures 208, the dielectric layer 116, and the etch stop layer 114 to be in electrical contact with the conductive features 112, as shown in FIG. 3. The barrier layer 138 and the seed layer 140 may be disposed between the conductive feature 142 and the passivation layer 130, the MIM structures 208, the dielectric layer 116, and the etch stop layer 114. The dielectric material 148 is disposed on the passivation layer 130 and the conductive features 142.

The present disclosure in various embodiments provides a device structure 100 including a dielectric layer 180 disposed between two dielectric layers 116, 182. The dielectric layer 180 has a k value greater than about 20 and a band gap less than about 5 eV. Some embodiments may achieve advantages. For example, the dielectric layer 180 can function as a current path to discharge static charge accumulated on the surfaces of the dielectric layers 116, 182 during plasma processes. As a result, device degradation is reduced.

An embodiment is a device structure. The device structure includes an interconnection structure disposed over a substrate, a first dielectric layer disposed over the interconnection structure, and a second dielectric layer disposed on the first dielectric layer. The second dielectric layer comprises a dielectric material having a k value greater than about 20 and a band gap less than about 5 eV. The structure further includes a third dielectric layer disposed on the second dielectric layer and a first conductive feature disposed on the third dielectric layer. The first conductive feature includes a first portion extending through the first dielectric layer, the second dielectric layer, and the third dielectric layer and a second portion disposed on the third dielectric layer.

Another embodiment is a device structure. The device structure includes an interconnection structure disposed over a substrate, and a metal-insulator-metal (MIM) structure disposed in the interconnection structure. The MIM structure includes a first electrode layer, a second electrode layer disposed over the first electrode layer, a first dielectric layer disposed between the first and second electrode layers, a third electrode layer disposed over the second electrode layer, and a second dielectric layer disposed between the second and third electrode layers. At least one of the first and second dielectric layers includes a dielectric material having a k value greater than about 20 and a band gap less than about 5 eV. The structure further includes a passivation layer disposed on the MIM structure and a conductive feature disposed over the passivation layer. The conductive feature comprises a first portion extending through the MIM structure and the passivation layer and a second portion disposed over the passivation layer.

A further embodiment is a method. The method includes depositing a first dielectric layer over an interconnection structure and depositing a second dielectric layer on the first dielectric layer. The second dielectric layer includes a dielectric material having a k value greater than about 20 and a band gap less than about 5 eV. The method further includes depositing a third dielectric layer on the second dielectric layer, forming an opening in the first, second, and third dielectric layers by a plasma process, and discharging static charge accumulated on surfaces of the first and third dielectric layers by the second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device structure, comprising:
an interconnection structure disposed over a substrate;
a first dielectric layer disposed over the interconnection structure;
a second dielectric layer disposed on the first dielectric layer, wherein the second dielectric layer comprises a dielectric material having a k value greater than about 20 and a band gap less than about 5 eV;
a third dielectric layer disposed on the second dielectric layer; and
a first conductive feature disposed on the third dielectric layer, wherein the first conductive feature comprises a first portion extending through the first dielectric layer, the second dielectric layer, and the third dielectric layer and a second portion disposed on the third dielectric layer.

2. The device structure of claim 1, wherein the second dielectric layer comprises TiO₂, TiO, BaO, or Ta₂O₅.

3. The device structure of claim 1, wherein the second dielectric layer has a thickness ranging from about 1 angstrom to about 20 angstroms.

4. The device structure of claim 1, further comprising an etch stop layer disposed between the interconnection structure and the first dielectric layer, wherein the first portion of the first conductive feature extends through the etch stop layer.

5. The device structure of claim 4, further comprising a fourth dielectric layer, wherein the etch stop layer is disposed on the fourth dielectric layer.

6. The device structure of claim 5, further comprising a second conductive feature, wherein the first conductive feature is electrically connected to the second conductive feature.

7. The device structure of claim 1, wherein the first conductive feature is a redistribution layer.

8. A device structure, comprising:
an interconnection structure disposed over a substrate;
a metal-insulator-metal (MIM) structure disposed in the interconnection structure, wherein the MIM structure comprises:
a first electrode layer;
a second electrode layer disposed over the first electrode layer;
a first dielectric layer disposed between the first and second electrode layers;
a third electrode layer disposed over the second electrode layer; and
a second dielectric layer disposed between the second and third electrode layers, wherein at least one of the first and second dielectric layers comprises a dielectric material having a k value greater than about 20 and a band gap less than about 5 eV;
a passivation layer disposed on the MIM structure; and
a conductive feature disposed over the passivation layer, wherein the conductive feature comprises a first portion extending through the MIM structure and the passivation layer and a second portion disposed over the passivation layer.

9. The device structure of claim 8, wherein the first and second dielectric layers comprise different materials.

10. The device structure of claim 9, wherein the first dielectric layer comprises TiO₂, TiO, BaO, or Ta₂O₅, and the second dielectric layer comprises an oxide of Li, Be, Mg, Ca, Sr, Sc, Y, Zr, Hf, Al, La, Ce, Pr, Nd, Sm, Eu, Gd, Tb, Dy, Ho, Er, Tm, Yb, Lu.

11. The device structure of claim 10, wherein the first dielectric layer has a first thickness, and the second dielectric layer has a second thickness greater than the first thickness.

12. The device structure of claim 11, wherein the k value of the first dielectric layer is greater than a k value of the second dielectric layer.

13. The device structure of claim 11, wherein the first thickness ranges from about 1 angstrom to about 20 angstroms.

14. The device structure of claim 8, wherein the first and second dielectric layers comprise the same material.

15. The device structure of claim 8, wherein the band gap of the dielectric material ranges from about 2.5 eV to about 4.5 eV.

16. The device structure of claim 8, wherein the k value of the dielectric material ranges from about 20 to about 60.

17. A method, comprising:
depositing a first dielectric layer over an interconnection structure;
depositing a second dielectric layer on the first dielectric layer, wherein the second dielectric layer comprises a dielectric material having a k value greater than about 20 and a band gap less than about 5 eV;
depositing a third dielectric layer on the second dielectric layer;
forming an opening in the first, second, and third dielectric layers by a plasma process; and
discharging static charge accumulated on surfaces of the first and third dielectric layers by the second dielectric layer.

18. The method of claim 17, wherein the first and third dielectric layers are deposited by plasma processes.

19. The method of claim 17, further comprising depositing an etch stop layer on the interconnection structure, wherein the first dielectric layer is deposited on the etch stop layer.

20. The method of claim 17, further comprising forming a conductive feature in the opening, wherein the conductive feature is in contact with the second dielectric layer.
